(19) United States
(12) Patent Application Publication
(10) Pub. No.: US 2003/0116432 A1
(43) Pub. Date: Jun. 26, 2003

(54) Adjustable throw reactor

(75) Inventors: Marc O. Schweitzer, San Jose, CA (US); Dinesh Saigal, San Jose, CA (US); Alan Liu, Mountain View, CA (US)

Correspondence Address: APPLIED MATERIALS, INC., 2881 SCOTT BLVD. M/S 2061, SANTA CLARA, CA, 95050, US

(73) Assignee: APPLIED MATERIALS, INC.

(21) Appl. No.: 10/036,320

(22) Filed: Dec. 26, 2001

(51) Int. Cl. C23C 14/34

(52) U.S. Cl. 204/298.11; 204/298.07; 204/298.19; 204/298.2; 204/298.23; 204/298.29

(57) ABSTRACT

Embodiments of the invention provide a processing apparatus having a lower reactor portion, an adjustable reactor wall portion attached to an upper portion of the lower reactor portion, the adjustable reactor wall portion being configured for selective linear expansion and contraction, and a source assembly positioned above the adjustable reactor wall portion. The cooperative operation of the source, adjustable wall, and the lower reactor creates a processing apparatus wherein the throw distance may be varied without disassembly of the reactor.

### BACKGROUND OF THE INVENTION

1. Field of the Invention

Embodiments of the invention generally relate to an apparatus and method for varying a throw distance in a processing system.

2. Background of the Related Art

Semiconductor integrated circuits typically contain several individual layers that may be classified according to whether the layer itself is a semiconductive layer, a dielectric or electrical insulator layer, or a conductive layer. With regard to conductive layers, which are often metal layers, the two primary methods for depositing a metal conductive layer are sputtering, which is also generally referred to as physical vapor deposition (PVD), and chemical vapor deposition (CVD). Of these two methods, PVD has the inherent advantages of utilizing a low cost source material while providing relatively high deposition rates. However, PVD has an inherent disadvantage in that it does not generally provide optimal bottom and/or sidewall coverage in deep narrow features, i.e., features having high aspect ratios. This disadvantage is generally a result of the fact that PVD is primarily an isotropic process that produces a ballistic-type pattern of sputtered particles that do not easily reach the bottom and side walls of deep narrow features. On the other hand, CVD is known to be a more conformal process that is generally effective in covering the bottom and sidewalls of high aspect ratio features. However, a disadvantage of CVD is that the deposition rate is generally substantially lower than deposition rates provided by PVD processes. Therefore, CVD deposition processes generally provide lower throughput rates than PVD deposition processes.

Conventional PVD reactors generally include a planar target manufactured from the deposition material that is positioned in parallel opposition to a substrate being sputter deposited. A negative electrical bias is applied to the target, where the electrical bias is calculated to be sufficient to ionize a processing gas introduced into the area between the target and the substrate. The positive ions from the process gas are then attracted to the negatively charged target with sufficient energy to sputter atoms of the target material therefrom. Some of the sputtered atoms strike the substrate and are deposited thereon. A magnetron may be positioned behind the target in order to create a magnetic field adjacent or parallel to the exposed surface of the target. The magnetic field operates to trap electrons and to maintain charge neutrality in the plasma, as well as increasing the ion density, which facilitates increased sputtering rates and better coverage within featured.

The semiconductor manufacturing industry has expended substantial effort in developing conductive layers that may be effectively sputtered into high aspect ratio features. High-density plasma (HDP) sputtering, for example, is a process that operates to excite a process or working gas into a high-density plasma. Typically, HDP sputter reactors use an RF power source connected to an inductive coil adjacent the plasma region to generate the high-density plasma. The working gas or process gas, which may be argon, for example, ion density causes a significant fraction of sputtered atoms to be ionized. If the pedestal electrode supporting the substrate being sputter coated is negatively electrically biased, then the ionized sputter particles are directionally accelerated toward the substrate, and therefore, are more effective in covering the bottom and sidewall portions of high aspect ratio features. HDP sputter reactors, however, have inherent disadvantages in that HDP systems are a relatively new technology and are relatively expensive when compared to conventional PVD systems. Furthermore, the quality of the sputtered films they produce is often not optimal, as HDP processes often produce an undulatory surface. Also, high-energy sputter ions tend to damage the material layers already deposited.

In response to the deficiencies of HDP systems, another sputtering technology, generally referred to as self-ionized plasma (SIP) sputtering, has been developed. SIP systems are generally based upon a standard capacitively coupled plasma sputter reactor having a planar target in parallel opposition to a substrate being sputter coated and a magnetron positioned behind the target for the purpose of increasing the plasma density. Therefore, SIP technology is generally characterized by a high target power density and a small magnetron having an outer magnetic pole piece enclosed within an inner magnetic pole piece, where the outer pole piece has a significantly higher total magnetic flux than the inner pole piece. In some implementations, the target may be separated from the substrate by a large distance in order to effect long-throw sputtering, which enhances collimated sputtering. However, the conversion from a long throw configuration to a shorter throw configuration generally involves substantial effort, such as reactor disassembly, for example.

SIP technology was originally developed to support sustained self-sputtering (SSS). In SSS a sufficiently high number of sputter particles are ionized such that they may be used to further sputter the target, without requiring additional working or process gases. Of the conductive layers, i.e., metal layers, commonly used in semiconductor fabrication, copper is known to facilitate SSS as a result of its high self-sputtering yield. The extremely low pressures and relatively high ionization fractions associated with SSS are advantageous for filling high aspect ratio features with copper. However, it was quickly realized that the SIP technology could also be advantageously applied to the sputtering of aluminum and other metals, and even to copper sputtering at moderate pressures. SIP sputtering generally produces high quality films exhibiting high feature fill characteristics, regardless of the material being sputtered. Nevertheless, SIP has some disadvantages. In particular, the small area of the SIP magnetron requires circumferential scanning rotary motion behind the target, and even with the rotary scanning method in place, radial deposition uniformity across the surface of the substrate is difficult to achieve. Furthermore, SIP processes generally require high target power, which is costly to generate, as high-capacity power supplies are expensive and necessitate complicated target cooling structures. Additionally, SIP tends to produce a relatively low ionization fraction of sputter particles, about 20%, for example. Also, the target diameter is typically only slightly greater than the substrate diameter in SIP systems. As a result, holes located at the edge of the substrate having radially outer sidewalls are more heavily coated than the radially inner sidewalls. Therefore, the sidewalls of the edge holes are generally asymmetrically coated.

FIG. 1 illustrates a cross sectional view of a conventional SIP reactor 100. Conventional reactor 100 is based on a modification of the Endura PVD Reactor that is commercially available from Applied Materials, Inc. of Santa Clara, Calif. Reactor 100 includes a vacuum reactor 112 that has a substrate support member 122 positioned in a bottom portion thereof. Reactor 112 includes a lid or upper surface 116 that operates to define a processing region 123 therein. Reactor 112 is electrically grounded and electrically isolated from lid portion 116 by an isolating member 114, and therefore, lid portion 116 also operates as a sputtering target for the deposition process. An annular cover ring 120 is positioned above the outer perimeter portion of the substrate support member 122, and operates to shield the outer portion of the substrate support member 122 from deposition. Substrate support member 122 is generally in electrical communication with a power supply 138, and therefore, substrate support member 122 may have an electrical bias applied thereto and act as an anode electrode. Substrate support member 122 may also include resistive heaters, coolant channels, and/or a thermal transfer gas cavity in order to allow the temperature of the substrate support member 122 and substrate 118 positioned thereon to be controlled during processing.

A shield 124 is positioned proximate a top portion of reactor 112 near target 116. Additionally, a grounded shield 126 separated by a second dielectric shield isolator 128 is positioned within reactor 112 immediately inward from the reactor walls. Shield 126 operates to protect the inner surface of the reactor walls from being coated by the material sputtered from target 116. The grounded shield 126 includes a downwardly extending portion 130, an inwardly extending bottom portion 132, and an upwardly extending inner portion 130 that terminates close to the cover ring 120. However, grounded shield 126 is not in electrical contact with clamp 120, as clamp 120 is generally in electrical communication with substrate support member 122, and therefore, clamp 120 is generally biased as a result of the connection of substrate support member 122 to power supply 138. Therefore, there may be a small gap 134 between clamp 120 and the upward portion 133 of shield 126. Therefore, grounded shield 126 acts as an anode grounding plane in opposition to the target 116, which may be set as a cathode, and thereby capacitively support a plasma. Some electrons deposit on the floating shield 124, and therefore a negative charge may build up there. This negative potential not only repels further electrons from the shield, but also confines the electrons to the main plasma area, thus reducing the electron loss, sustaining low-pressure sputtering, and increasing the plasma density.

A selectable DC power supply 136 negatively biases the target 116 to a negative voltage with respect to the grounded shield 126 in order to ignite and maintain the plasma. The negative voltage may be, for example, between about −400 to −600 volts DC. A target power of between about 1 and 5 kW may be applied in order to ignite the plasma, while a power of greater than 10 kW is generally preferred for conventional SIP sputtering processes.

Conventionally, the substrate support member 122 and the wafer 118 were left electrically floating, however a negative DC self-bias nonetheless developed on them. On the other hand, some conventional designs use the controllable power supply 138 to apply a DC or RF bias to the substrate support member 122 in order to further control the negative DC bias thereon. A gas source 140 supplies a working or process gas, typically the chemically inactive noble gas argon, through a mass flow controller 142 to a gas inlet 144 located at the lower portion of the reactor 112 in back of and below the grounded shield 126. The gas enters the main processing space between the target 116 and the wafer 118 through the gap 134 between the grounded shield 126 and the pedestal 122 and the clamp 120. A vacuum pump system 146 connected to the reactor 112 through a wide pumping port 148 on the side of the reactor opposite the gas inlet 144 maintains the reactor at a low pressure. Although the base pressure can be held to about 10⁻⁷ Torr or lower, the pressure is typically maintained at about or below 1 milliTorr for SIP sputtering of metals. A computer-based controller 150 controls the reactor, including parameters such as the DC target power supply 136, the bias power supply 138, the mass flow controller 142, and the vacuum system 146.

To provide efficient sputtering, a magnetron 154 is positioned behind the target 116. Magnetron 154 includes opposed magnets 156, 158 connected and supported by a magnetic yoke 160. The magnetic field generated by magnetron 154 operates to trap electrons and to increase the ion density in order to form a high-density plasma region 162 close to the target 116. The magnetron 154 is rotated about the center 164 of the target 116 by a motor-driven shaft 166 to achieve full coverage in sputtering the target 116.

However, one problem associated with the conventional type SIP reactors shown in FIG. 1 is that the throw distance may not be easily adjusted to accommodate the deposition of various layers. Inasmuch as various processes conducted in an SIP reactor generally require varying throw distances in order to optimize the deposition characteristics of the respective layers, it is desired to have an SIP reactor that is configured to provide an adjustable throw distance.

### SUMMARY OF THE INVENTION

Embodiments of the invention generally provide a processing apparatus having a lower reactor portion, an adjustable reactor wall portion attached to an upper portion of the lower reactor portion, the adjustable reactor wall portion being configured for selective linear expansion and contraction, and a source assembly positioned above the adjustable reactor wall portion. The cooperative operation of the source, adjustable wall, and the lower reactor creates a processing apparatus wherein the throw distance may be varied without disassembly of the reactor.

Embodiments of the invention further provide an improved self ionizing plasma reactor, wherein the reactor includes a reactor body portion having a generally annular wall and a base member and a selectively adjustable upper reactor wall positioned above the reactor body. The reactor further includes a device for adjusting the selectively adjustable upper reactor wall, the device for adjusting being in communication with the selectively adjustable upper reactor wall, and a source assembly positioned above the selectively adjustable upper reactor wall. Therefore, the selectively adjustable upper reactor wall may be used to adjust the throw distance of the reactor within a processing recipe or within a recipe step, without disassembly of the reactor.

Embodiments of the invention further provide a plasma reactor that includes a lower reactor portion having a substrate support member positioned therein and an adjustable reactor wall portion positioned above the lower reactor portion. The plasma reactor additionally includes a source assembly positioned above the adjustable reactor wall portion and a device for actuating the adjustable reactor wall portion, the device for actuating being in communication with the lower reactor portion and the source assembly. Thus, the device for actuating may be used to adjust the throw distance of the reactor during a processing sequence.

### BRIEF DESCRIPTION OF THE DRAWINGS

So that the manner in which the above recited features of the present invention are attained and may be understood in detail, a more particular description of the invention, briefly summarized above, may be had through reference to the embodiments thereof, which are illustrated in the appended drawings. It is to be noted, however, that the appended drawings illustrate only typical or exemplary embodiments of the invention, and are therefore, not to be considered limiting of its scope, as the invention may admit to other equally effective embodiments.

FIG. 1 illustrates a conventional SIP processing reactor.

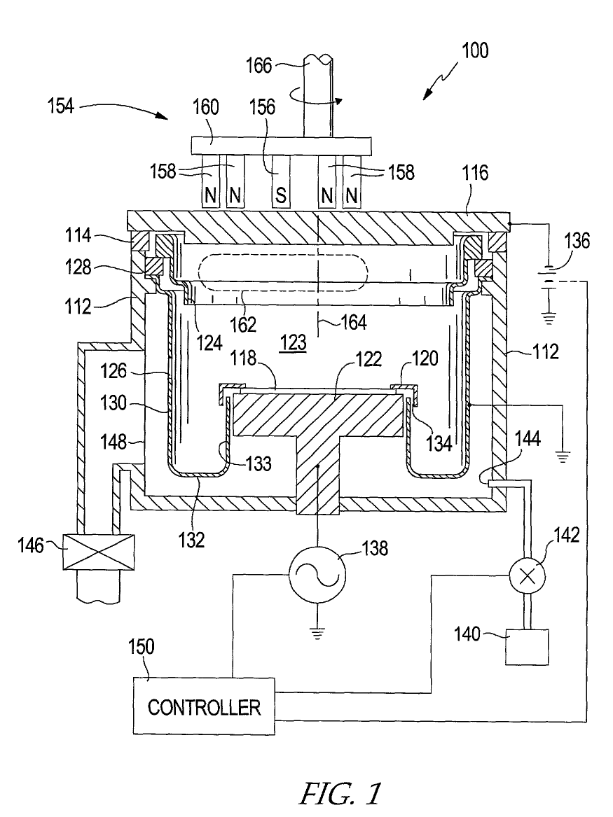

FIG. 2 illustrates a simplified perspective view of an exemplary processing system of the invention.

FIG. 3 illustrates a sectional view of the exemplary processing reactor of FIG. 2.

FIGS. 4a and 4b illustrate exemplary adjustable reactor wall configurations.

FIG. 5 illustrates a detailed sectional view of an exemplary processing system of the invention.

### DETAILED DESCRIPTION OF THE PREFERRED EMBODIMENT

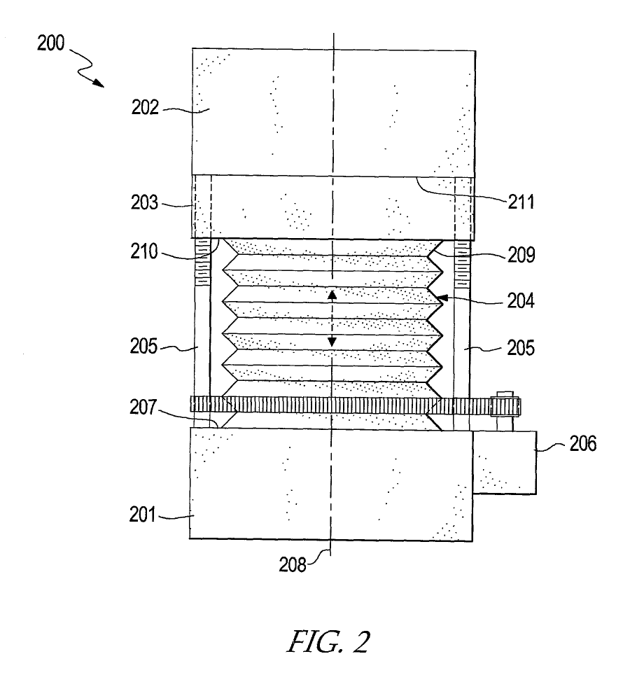

FIG. 2 illustrates a perspective view of an exemplary processing reactor 200 of the invention. Processing reactor 200 includes a lower reactor portion 201 in communication with an adjustable upper reactor wall 204 at an upper surface 207 of the lower reactor portion 201. The lower reactor body 201 generally includes an annular reactor wall portion and a base or floor portion. The adjustable upper reactor wall 204 extends from the upper surface 207 of the lower reactor portion 201 about an axis 208 of the lower reactor 201, i.e., adjustable reactor wall 204 and lower reactor portion 201 may share a common axis 208. An upper end 209 of the adjustable upper reactor wall 204 is in communication with a lower surface 210 of a reactor adaptor 203. An upper end 211 of reactor adaptor 203 is in communication with a processing source assembly 202, and therefore, adaptor 203 operates to connect the adjustable upper reactor wall 204 to the processing source assembly 202. Adjustable upper reactor wall 204 additionally includes a device 205 for selectively adjusting the linear spacing of reactor wall 204, i.e., device 205 is configured to selectively adjust the distance between the upper surface 207 of lower reactor portion 201 and the lower surface 210 of adaptor 203 via extension or contraction of the adjustable reactor wall 204. The device 205 for adjusting the spacing of adjustable upper reactor wall 204 may be in communication with an actuator 206 for selectively controlling the linear spacing of adjustable reactor wall 204.

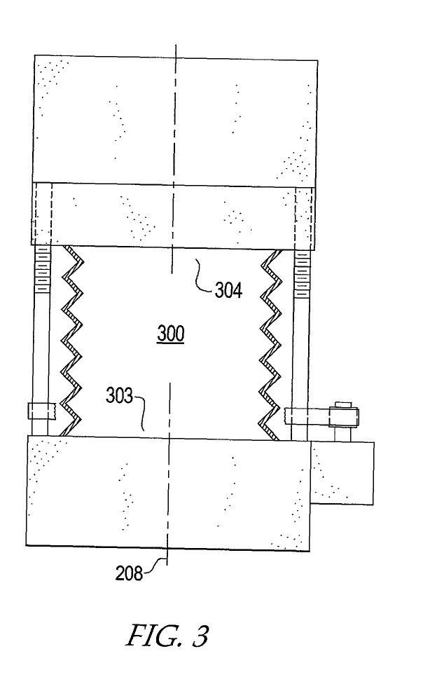

The cooperative assembly of the lower reactor portion 201, the adjustable upper reactor wall 204, the adaptor 203, and the source assembly 202 forms an interior processing region 300, as shown in FIG. 3. The radius of the processing region 300 is generally defined by the interior surfaces of the lower reactor portion 201 and the adjustable upper reactor wall 204. The linear height of the processing region 300, as measured along axis 208 for example, is defined at a lower end of processing region 300 by the bottom 303 of lower reactor portion 201. The height of processing region 300 is defined at an upper end by the lower portion 304 of source 202, which generally corresponds to the lower surface of the source target, and therefore, the linear height of processing region 300 may be measured as the distance from the bottom 303 of lower reactor portion 201 to the lower surface 304 of the source 202. Therefore, the volume of processing region 300 may generally be calculated or approximated from the linear height (h) of processing region 300 and the radius (r) of the processing region (V=π·r².h)

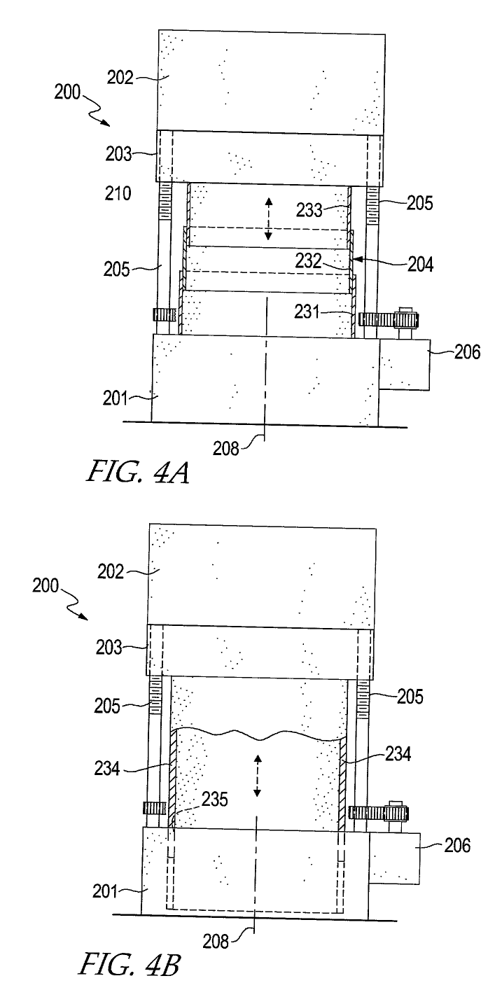

Adjustable upper reactor wall 204 may be manufactured from a plurality of mechanical configurations, such as a bellows-type assembly (shown in FIG. 2), a plurality of slidably adjustable telescopic reactor wall members (shown in FIG. 4a), a slidably adjustable single reactor wall member configured to be partially received in a lower portion of a reactor body positioned below (shown in FIG. 4b), or other configurations known to be selectively extendable. Regardless of the specific configuration, the adjustable upper reactor wall 204 is configured to connect a lower reactor portion 201 to an adaptor 203 or directly to a source assembly 202, while maintaining a vacuum, i.e., adjustable reactor wall 204 may linearly expand or contract while maintaining a vacuum in processing region 300. The device 205 for selectively adjusting the linear spacing of reactor wall 204 may comprise one or more jackscrew assemblies 205, for example, attached at a first end to the lower reactor portion 201 and at a second end to the adaptor 203 or the source assembly 202. Thus, jackscrew assemblies 205 may operate to increase or decrease the separation distance between lower reactor portion 201 and source assembly 202 via extension or contraction of adjustable wall 204. The jackscrew assemblies 205 may be in mechanical engagement with a stepping motor actuator 206 configured to impart precise rotational motion to the jackscrew assemblies. Aside from jackscrew assemblies, various other mechanical devices may be used to adjust the spacing of adjustable reactor wall 204, such as, for example, linear gear assemblies, linear hydraulic actuators, screw drives, or other mechanical devices known to be effective in adjusting linear spacing of mechanical devices.

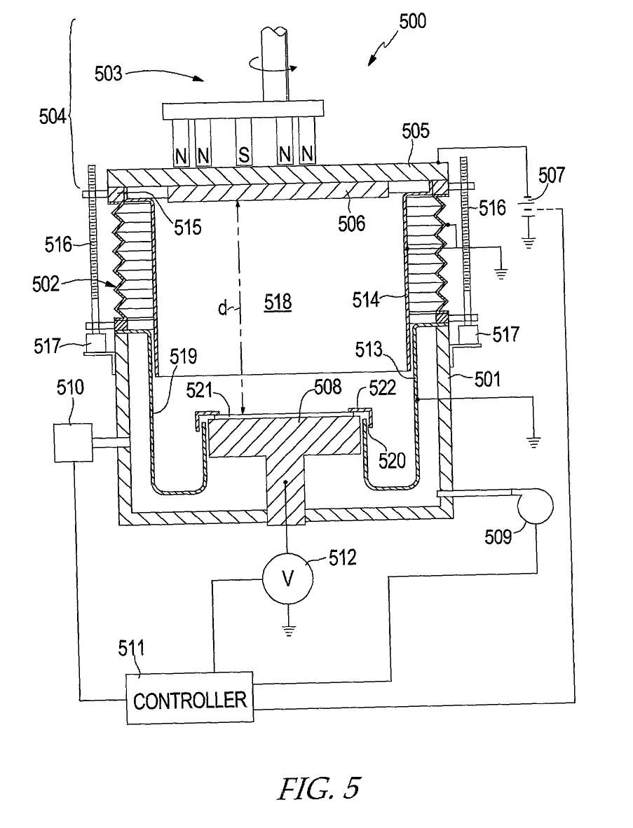

FIG. 5 illustrates a detailed sectional view of an exemplary processing reactor of the invention. The exemplary processing reactor 500 includes a lower reactor body 501, which may define a generally circular interior region having an open upper portion. Lower reactor body 501 includes a substrate support member 508 positioned therein, wherein substrate support member 508 is configured to support a substrate 521 thereon for processing. The substrate support member 508 may be in electrical communication with a power supply 512 configured to apply an electrical bias thereto, if a biased semiconductor process is implemented. The substrate 521 may be secured to substrate support member 508, both mechanically and electrically, immediately below an annular shield ring 522 that may be attached to the perimeter of the substrate support member 508. Shield ring 508 operates to cover the outer perimeter of substrate support member 522 in order to prevent deposition from occurring on the substrate support member 508. Lower reactor body 501 further includes a generally annular lower shield member 513 attached to a top portion of reactor body 501 and extending downwardly therefrom. Lower shield member 513, which is electrically grounded, includes a lower portion that returns upwardly toward the perimeter of the substrate support member 508. The terminating end of the return portion may be received proximate the perimeter of the substrate support member 508, immediately inward from the annular shield ring 522. However, the terminating end of the lower shield member 513 generally does not contact the annular shield member 522 or the substrate support member 508 during processing, as these elements generally have an electrical bias applied thereto during processing time periods, while the lower shield member is generally grounded. Thus, it is desirable to maintain lower shield member 513 electrically isolated from the annular shield 522 of the substrate support member 508 during processing time periods. Reactor body 501 may also include a pumping system 509 and a process gas supply system 510, both of which are in communication with the interior portion of reactor body 501.

Processing reactor 500 further includes a bellows-type upper reactor wall 502. Bellows-type upper reactor wall 502, which will be generally referred to herein as the “adjustable reactor wall 502,” is attached at a lower end to an upper portion of reactor body 501 and extends upwardly therefrom, generally in the same direction that the walls of reactor body 501 extend from a bottom portion thereof. Adjustable reactor wall 502 attaches at an upper end to an adaptor 515. Adaptor 515 includes an upper shield member 514 attached to an interior portion thereof. Upper shield member 514, which may be electrically grounded or floating, is generally a cylindrically shaped shield that attaches to the adaptor 515 and extends downwardly toward the reactor body 501. Upper shield member 514 is generally sized to be received inward of the lower shield member 513, without contacting lower shield member 513. Adaptor 515 also includes a jackscrew assembly 516 attached thereto. The jackscrew assembly 516 generally includes an upper and lower ends, and the upper end is attached to the adaptor 515 and the lower end is attached to the reactor body 501.

The adaptor 515 is attached to a source assembly 503. Source assembly 503 generally includes a magnetron assembly 504 positioned above a reactor lid member 505. Lid member 505 includes a target 506 positioned on a lower surface thereof, the target 506 being in electrical communication with a power supply 507. The composition of target 506 may be selected in accordance with processing requirements, i.e. the target may be selected as the deposition material. Lid portion 505 is generally electrically isolated from the adaptor 515 and the other reactor elements.

Reactor 500 also includes a controller 511 that is in communication with the gas supply 510, power supplies 512 and 507, pumping system 509, and actuators 517. Controller 511, which may be a microprocessor based control system, for example, may be configured to control the parameters of the processing system 500 in accordance with a predetermined processing recipe.

In operation, reactor 500 may be used to implement multiple long-throw type deposition processes into a single reactor. For example, reactor 500 may be used to deposit a first layer on a substrate 521 using a throw distance “x”. Thereafter, during the same processing sequence, i.e., within a processing recipe or recipe step, the throw distance may be adjusted to distance “y” for the deposition of a second layer on the substrate, wherein x≠y. The adjustment of the throw distance from x to y may be accomplished by activating actuators 517 such that jackscrews 516 cause the distance (d) between the target 506 and substrate support member 508 to vary. The adjustment is made possible as a result of the bellows-type reactor wall 502 being linearly adjustable. The adjustment of the throw distance (d) may be accomplished between recipe steps of a processing recipe, within a recipe step of a processing recipe, or between processing recipes.

More particularly, the adjustment of the throw distance (d) to shorten the distance d, for example, includes activating the jackscrews such that the source assembly 503 is caused to move toward the reactor body 501. As such, the bellows-type reactor wall 502 is caused to compress or fold together so that the distance between the source assembly 503 and the reactor body 501 may be decreased. When the distance d is decreased, the upper shield member 514, which is attached to the adaptor 515, lowers with the adaptor 515 and the source assembly 503. Upper shield member 514 is therefore configured to be received concentrically within the lower/outer shield member 513. This configuration allows for shields 513 and 514 to cooperatively protect the interior of processing system 500 from deposition.

Processing reactor 500 may, for example, be used as a single metal deposition reactor for use in Ti/TiN deposition in conjunction with a CVD W deposition process. In this particular process, the Ti bottom coverage is important for the formation of low resistance contacts, and generally requires a long throw distance. However, both the conformal coverage and the deposition rate suffers substantially in the TiN deposition process at long throw distances. Therefore, the exemplary processing reactor 500 may be used for a Ti/TiN deposition process, wherein the throw distance is initially set to a long throw value “x” for a Ti deposition recipe step. Once the Ti deposition step is complete, then the throw distance may be adjusted to a much shorter distance that is calculated to accommodate optimal TiN deposition in a second recipe step. During the transition between recipe steps, the throw distance may be adjusted without depressurizing reactor 500 and manually adjusting the throw distance, as with conventional reactor configurations. Another exemplary application for reactor 500 may be in a copper barrier/seed layer deposition process. In this process the throw distance may be initially set to facilitate optimal barrier layer deposition in a first recipe step, and then adjusted to accommodate optimal seed layer deposition in a second recipe step conducted in the same reactor. Further still, embodiments of the present invention may be utilized to maintain the spacing between the target and substrate, despite the erosion of the target surface from deposition, i.e., the adjustable throw of the reactor of the invention may be controlled in order to compensate for the surface erosion of the target.

In the exemplary embodiment of the invention illustrated in FIG. 4a, the adjustable reactor wall 204 comprises at least two annular wall members telescopically received within each other. In this exemplary embodiment, a lower wall member 231 is fixedly attached to the lower reactor portion 201. A second reactor wall portion 232 having a smaller radius than wall portion 231 is positioned above wall portion 231 and is configured to be telescopically received within wall portion 231. A third wall portion 233 having a smaller radius than wall portion 232 is positioned above wall portion 232 and configured to be telescopically received within wall portion 232. Walls 231, 232, & 233 cooperatively form an adjustable reactor wall configured to define a processing region 300. The respective walls may include sealing devices positioned on the wall members such that the walls may be telescopically received within each other and still maintain a vacuum in the processing region 300 defined by the walls. Therefore, through selective contraction or extension of the telescopically received wall members 231, 232, & 233, the throw distance d may be adjusted.

In the exemplary embodiment of the invention illustrated in FIG. 4b, the adjustable reactor wall comprises a unitary reactor wall member 234. Wall member 234 defines processing region 300 and may be received in an annular slot 235 formed into the lower portion 201 of the reactor. Thus, when the throw distance is to be decreased, wall member 234 may be further received in slot 235 such that the source 202 is brought closer to the lower reactor portion 201. Similarly, when the throw distance is to be increased, wall member 234 may be extended outward from slot 235 to increase the distance from the lower reactor portion 201 to the source 202. Therefore, through selective adjustment of the vertical position of wall member 234, the throw distance d may be adjusted.

Additionally, although embodiments of the invention are described above with respect to a bellows-type adjustable reactor wall, other mechanical apparatuses capable maintaining a vacuum in the processing reactor while allowing for linear adjustment are contemplated within the scope of the invention. Furthermore, although jackscrews are primarily discussed above as devices that may be used to adjust the linear position of the adjustable reactor wall, i.e. the throw distance, various other mechanical devices are contemplated within the scope of the invention.

While the foregoing is directed to the preferred embodiment of the present invention, other and further embodiments of the invention may be devised without departing from the basic scope thereof, and the scope thereof is determined by the claims that follow.

1. A processing apparatus, comprising:
a lower reactor portion;
an adjustable reactor wall portion attached to an upper portion of the lower reactor portion, the adjustable reactor wall portion being configured for selective linear expansion and contraction; and
a source assembly positioned above the adjustable reactor wall portion.

2. The processing apparatus of claim 1, wherein the adjustable reactor wall portion comprises a bellows-type adjustable reactor wall.

3. The processing apparatus of claim 1, wherein the adjustable reactor wall portion comprises a telescoping reactor wall.

4. The processing apparatus of claim 1, wherein the adjustable reactor wall comprises a unitary reactor wall configured to be adjustable via a receiving channel formed into the lower reactor portion.

5. The processing apparatus of claim 2, wherein the bellows-type adjustable reactor wall further comprises an annular bellows member attached at a first annular end to an upper portion of the lower reactor body and at a second annular end to at least one of an adaptor and a source assembly.

6. The processing apparatus of claim 1, further comprising a telescopic shield member.

7. The processing apparatus of claim 1, further comprising:
a first shield member attached proximate an upper portion of the processing apparatus within a processing region; and
a second shield member attached proximate a lower portion of the processing apparatus, the first shield member being telescopically received within the second shield member when the adjustable reactor wall portion is linearly adjusted.

8. The processing apparatus of claim 1, further comprising a device for selectively adjusting a linear spacing of the adjustable reactor wall portion.

9. The processing apparatus of claim 8, wherein the device for selectively adjusting the linear spacing comprises:
at least one jackscrew assembly attached at a first end to lower reactor portion and at a second end to the source assembly; and
at least one jackscrew actuator in communication with each of the at least one jackscrews, the actuators being configured to selectively impart rotational motion to the jackscrews.

10. The processing apparatus of claim 1, wherein the source assembly comprises a magnetron assembly and a target.

11. The processing apparatus of claim 1, wherein the lower reactor portion comprises a reactor body having annular side walls and a bottom portion, the bottom portion having a substrate support member concentrically positioned thereon.

12. An improved self ionizing plasma reactor, comprising:
a reactor body portion having a generally annular wall and a base member;
a selectively adjustable upper reactor wall positioned above the reactor body;
a device for adjusting the selectively adjustable upper reactor wall, the device for adjusting being in communication with the selectively adjustable upper reactor wall; and
a source assembly positioned above the selectively adjustable upper reactor wall.

13. The reactor of claim 12, wherein the selectively adjustable upper reactor wall comprises an annularly shaped bellows-type reactor wall, the bellows-type reactor wall being attached at a first end to the reactor body and at a second end to at least one of an adaptor member and the source assembly.

14. The reactor of claim 12, wherein the selectively adjustable upper reactor wall comprises a telescopic wall member attached at a first end to the reactor body portion and at a second end to at least one of the source assembly and an adaptor member.

15. The reactor of claim 12, wherein the selectively adjustable upper reactor wall comprises a unitary cylindrically shaped wall member configured to be sealably received in a receiving channel of the reactor body portion.

16. The reactor of claim 12, wherein the device for adjusting comprises a jackscrew assembly.

17. The reactor of claim 16, wherein the jackscrew assembly further comprises at least one jack screw in communication with an actuating stepping motor.

18. The reactor of claim 12, wherein the device for adjusting comprises at least one of a hydraulic actuator and a linear gear assembly.

19. A plasma reactor, comprising:
a lower reactor portion having a substrate support member positioned therein;
an adjustable reactor wall portion positioned above the lower reactor portion;
a source assembly positioned above the adjustable reactor wall portion; and
a device for actuating the adjustable reactor wall portion, the device for actuating being in communication with the lower reactor portion and the source assembly.

20. The plasma reactor of claim 19, wherein the adjustable reactor wall portion comprises a bellows-type reactor wall.

21. The plasma reactor of claim 19, wherein the adjustable reactor wall portion comprises an upper reactor wall configured to be linearly adjustable through expansion and contraction of the wall portion.

22. The plasma reactor of claim 19, wherein the device for actuating comprises at least one jack screw assembly.
